(19) United States
(12) Patent Application Publication
(10) Pub. No.: US 2011/0247689 A1
(43) Pub. Date: Oct. 13, 2011

(54) SUBSTRATE FOR AN OPTOELECTRONIC DEVICE

(76) Inventors: Peter Chabrecek, Freidorf (CH); Hanspeter Meier, Schachen (CH); Frank Nueesch, Wangen (CH); Matthias Rosenfelder, Grub SG (CH); Fernando Araujo de Castro, Uster (CH)

(21) Appl. No.: 13/127,407

(22) PCT Filed: Nov. 4, 2009
(86) PCT No.: PCT/EP09/07894

§ 371 Date: Jun. 27, 2011

(30) Foreign Application Priority Data
Nov. 5, 2008 (DE) 10 2008 055 969.5

(51) Int. Cl. H01L 31/0392; H01L 29/02; H01L 33/02

(52) U.S. Cl. 136/256; 257/88; 257/528; 257/E33.055; 257/E29.002

(57) ABSTRACT

A substrate for an optoelectronic device, with a fabric of monofilaments and/or fibres of a polymer, which is designed for purposes of implementing and/or supporting an electrode layer, wherein the fibres have a fibre diameter of between 20 μm and 100 μm, in particular of between 30 μm and 80 μm, the fabric has mesh openings that implement an open surface area of 70% to 85%, and the fabric is provided with a coating having a transparent, electrically non-conducting polymer material such that the fibres are at least partially surrounded by the polymer material.

### BACKGROUND OF THE INVENTION

The present invention concerns a substrate for an optoelectronic device.

From the prior art there are numerous methods of known art for the implementation of a supporting layer (substrate) for an optoelectronic device, such as a solar cell. Here in the first instance the provision of the so-called first-generation silicon substrate is of known art and in widespread use in the case of solar cells.

In recent times, in particular, these products are displaying increasing efficiency, both with regard to electrical efficiency, and also (mass) manufacturability, at the same time the fundamental costs, including the material costs of the silicon, are now as before too high to allow solar cells of this kind to be used more widely.

So-called solar cells of the second generation no longer require silicon. Here with the aid of various deposition technologies, such as plasma sputtering, or CVD, onto a transparent substrate, typically a glass plate, or a flexible polyamide, a cost advantage is achieved in terms of the more favourably priced substrate, now as before, however, even for this second generation substrate costs still appear to be in need of improvement (as is, incidentally, also their flexibility in deployment).

Efforts are therefore being made with so-called photovoltaic technologies of the third generation to reduce the substrate costs (as a significant cost driver) further, while now as before justifiable efficiencies (typically approx. 10%) must be achieved. Key technologies for purposes of achieving these objectives assume on the one hand low price substrates (such as films or fabric) for the active components, on the other hand, manufacturing processes at low temperature and ambient pressure (as in digital or screen printing) as well as a high rate of manufacture. It is anticipated that, in particular, organic solar cells, tandem cells, or so-called DSC solar cells (dye-sensitised nano-structured solar cells) offer the potential to achieve these objectives.

While moreover, semiconductor-based substrates are dominant now as before in the above-described silicon-based solar cells of the first generation, non-semiconductor-based substrates are increasingly appearing as effective and technological alternatives. Thus, for example, the ability of some non-Si photovoltaic materials, to generate current at low incident light angles, or low light intensity, or even with polarised light sources (a broader light spectrum is also utilised) prove to be advantageous compared with silicon, the advantages of flexible substrates (that is to say, e.g. on a film or fabric base) are equally appreciated, if solar cells must be rolled or folded, or other free-form flexibilities are required for various application environments . At the same time, however, now as before, there is a lack of a low price, efficient substrate material, in particular one that is also simple and reliable to manufacture in large numbers, for optoelectronic devices such as, for example, solar cells.

The object of the present invention is therefore to create a generic substrate for an optoelectronic device, in particular a photovoltaic or solar cell (or OLED), which with improved optical properties, in particular transmission properties for interacting active layers, enables a simplified manufacturability, in particular suitable for high volume production, with low material and manufacturing costs and high reproducibility.

### SUMMARY OF THE INVENTION

The object is achieved by means of the substrate for an optoelectronic device, with a fabric of monofilaments and/or fibres of a polymer, which is designed for purposes of implementing and/or supporting an electrode layer, wherein the fibres have a fibre diameter of between 20 μm and 100 μm, in particular of between 30 μm and 80 μm, the fabric has mesh openings that implement an open surface area of 70 to 85%, and the fabric is provided with a coating of a transparent, electrically non-conducting polymer material, such that the fibres are at least partly surrounded by the polymer material, the coating is applied such that the substrate on a first uncoated side of the surface is electrically conducting, and on a second, coated side of the surface is electrically non-conducting.

In accordance with the invention, the fibres deployed for the manufacture of the fabric are in the first instance advantageously established or selected such that they have a fibre diameter of between 20 μm and 100 μm, in particular of between 30 μm and 80 μm—typically the fibres for a respective form of implementation have a constant diameter. In addition, within the framework of the invention the fabric is advantageously configured such that the mesh openings formed between the woven fibres implement an open surface area of between approx. 70% and approx. 85%; this signifies that the remaining 15% to 30%, with reference to the total surface area, is occupied by the fibres.

Furthermore in accordance with the invention the fabric is advantageously provided at least on one side with a transparent coating in the form of a (e.g. partial) filling, which is implemented in terms of an electrically non-conducting polymer.

In this manner it can advantageously be implemented in accordance with the invention that the substrate on a first side (uncoated surface side) is electrically conducting, since here electrically conducting fibres and/or an electrically conducting coating of the fabric are not affected by the transparent polymer coating, while on the other side (on the second coated surface side) the transparent polymer material provides electrical insulation.

The polymer material can furthermore be provided, in particular coated, with ORMOCER, or SiOx, or another inorganic material.

Advantageously the polymer material thus coated as required, or the transparent, electrically non-conducting coating formed therewith, provides the substrate (and thus of an optoelectronic device constructed thereon) with moisture and/or UV resistance (e.g., by means of a suitable admixture of a UV absorber); in addition this coating material acts advantageously in terms of further development as an oxidation barrier.

With a coating thickness that is established to be smaller than a fabric thickness, typically approx. 70% to 80% of the fabric thickness, and that at least partially penetrates the fabric, it is thus possible to implement a substrate arrangement that is compact, optically and physically efficient, and at the same time can be manufactured simply and at low cost.

In accordance with a preferred further development of the invention a material is selected for the polymer material, which can be an acrylic resin, a silicon material a fluoropolymer, or a polymer selected from a group consisting of PU, PEN, PI, PET, PA, EVA or comparable materials, further preferred thermally-cured or radiation-cured, wherein in particular a UV radiation-cured coating has been proven to be particularly preferred.

With regard to the fibres in accordance with the invention the invention in the first instance encompasses the manufacture of the fabric essentially from electrically non-conducting fibres, which then for purposes of implementing the electrode action are provided with an electrical conductivity. Suitable fibres are, in particular, semitransparent monofilaments of PA, PP, PET, PEEK, PI, PPS or similar chemical fibres.

For purposes of producing the electrical conductivity, wherein preferably, the fabric deployed for the substrate in accordance with the invention has a surface resistance<50 Ω/sq, preferably<20 Ω/sq, further preferred less than 10 Ω/sq, the invention on the one hand encompasses, in terms of further development, the provision of fibres in the fabric that consist of metal (metal fibres) or as fibres carry a form of metallisation. Suitable metals for purposes of implementing the metal fibres are, for example, Ti, Ag, Al, Cu, Au, Pa, Pt, Ni, W, Mo, Nb, Ba, Sn, Zr or similar, wherein the conductivity of the fabric (or the surface resistance) can be suitably established by means of the geometry, with which such a metallic or metallised thread is woven together with non-conducting threads. The framework of suitable forms of embodiment of the invention thereby includes the provision of conducting threads of this kind in the form of a 1:1 interlacing, or preferably 1:2, 1:3, or higher, as a supplement or alternative to the selection of the direction (warp, fill), in which a metallic or metallised fibre should actually be woven, so as to undertake the adjustment of the conductivity (also envisaged in particular is weaving in both the warp and fill directions).

On the other hand, it is possible and envisaged, within the framework of preferred forms of implementation of the invention, to establish the electrical conductivity, i.e. the low ohmic surface resistance required, by means of a metallisation of the fabric, the latter then typically consisting exclusively of non-conducting polymer fibres (where in principle metallic fibres can here too be woven in). A metallic coating of the fabric of this kind can suitably be made by means of plasma sputtering (e.g. with Ag, Au, Ti, Mo, Cr, Cu, ITO, ZAO or similar), alternatively, by means of vaporisation (Al, Ag, Cu, etc.) or by means of wet chemical methods such as electrolysis featuring, for example, the deposition of Ag, Ni. Typically a metallisation of the fabric of this kind produces a particularly high conductivity, which results in a surface resistance<10 Ω/sq.

As already stated in the introduction a particular advantage of the invention is in the high level of transparency, or transmission, of the substrate implemented in accordance with the invention. This can be particularly favourably influenced by adjustment of the mesh openings established in accordance with the invention, wherein methods of known art for the manufacture of precision fabrics can in particular be applied here to advantage. For the implementation of the mesh openings envisaged in accordance with the invention with an open surface area in accordance with the invention of between 70% and 85% it has proved to be particularly preferable to adjust mesh widths to be in the range between 200 μm and 300 μm, i.e. to establish the surface area of a respective mesh opening (preferably constant over the surface) in a range between approx. 80,000 μm² and approx. 800,000 μm².

In accordance with the invention advantageously moreover, as a rule, the total transmission (in %) of a substrate manufactured in accordance with the invention is higher than the open surface area; in addition to the so-called direct transmission, namely of the passage of light through the meshes, and also through transparent fibres, there is also a diffusive transmission, which (for example in the case of metallic coated fibres), takes account of a reflection on the fibre or through the fibre, so that as a result, for a range of open surface areas in accordance with the invention of between 70% and 85%, an actual total transmission of between 75% and 95% can be achieved.

The present invention thus enables in a potentially simpler, more elegant and lower cost manner the manufacture of optoelectronic devices for a multiplicity of applications. While the photovoltaics may be the main application for the present invention, wherein in particular organic solar cells, thin layer cells, DSC cells or tandem cells can be applied onto the substrate in the manner in accordance with the invention, the implementation of other optoelectronic devices with the substrate is equally advantageous and encompassed by the invention. These include organic LEDs, other display technologies, various passive electronic components, or even large surface area components such as are deployed, for example, in architectural applications, or similar.

Thus one can anticipate that the present invention not only implements numerous advantages, for example, compared with the TCO electrodes (transparent conductive oxide, used as a transparent electrode) of known art, such as, for example, significantly lower manufacturing and material costs. the lack of a requirement for a special vacuum facility (TCOs must be manufactured under a high vacuum), simpler technology with increased conductivity as well as reduced brittleness and improved substrate adhesion; the possibility may also be opened up, actually only by means of the substrate presented in accordance with the invention, of configuring large surface area, flexible surfaces as optoelectronic devices, in particular for photovoltaic purposes (and also for the manufacture of OLEDs).

### BRIEF DESCRIPTION OF THE DRAWINGS

Further advantages, features, and details of the invention ensue from the following description of preferred examples of embodiment and also with the aid of the drawings; these show in:

FIG. 1 a substrate in accordance with a first preferred form of embodiment of the invention in a sectioned side view;

FIG. 2 an alternative form of implementation of a substrate in accordance with a second preferred form of embodiment;

FIG. 3 a schematic sectioned view of an organic solar cell, implemented by means of the substrate of the first form of embodiment as per FIG. 1; and

FIG. 4 a further form of embodiment of the present invention, in which the coating is introduced into the fabric such that an electrically conducting layer can be achieved on both sides, and such that, for example, a tandem solar cell can be constructed.

### DETAILED DESCRIPTION

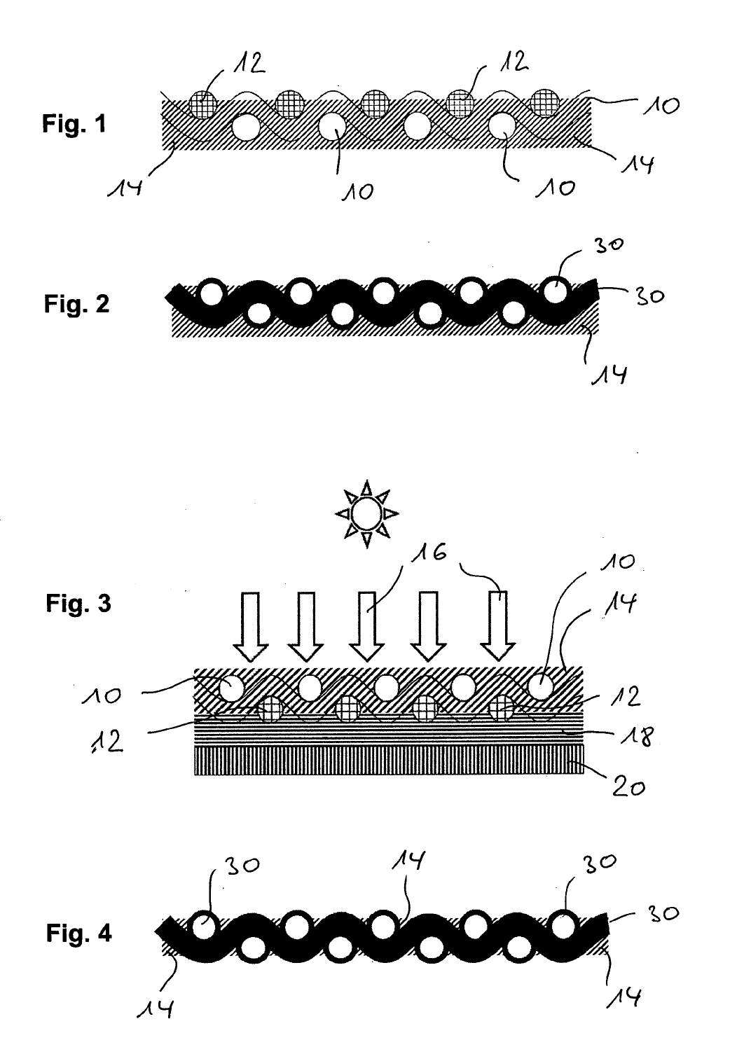

FIG. 1 shows in the schematic sectioned side view a fabric of transparent PA fibres 10, which have a thickness in the range between 30 μm and 35 μm. Each second fibre in the warp (alternatively, also in the fill) is an Al metal thread 12 of a comparable thread thickness in the range between approx. 30 μm and 35 μm.

This fabric is provided with a coating 14 of a transparent polymer (here a UV-cured acrylic resin) such that on one side (in FIG. 1 below) the coating 14, which with approx. 60 μm achieves 75% to 85% of the layer thickness of the fabric 10, 12, forms an insulating layer, while in the upper region, with the at least partially exposed metal fibres 12, the arrangement is electrically conducting and can act as an electrode. The coating 14 is thereby applied such that it partially penetrates the fabric, i.e., the effective thickness of the coating overlaps with a layer thickness of the fabric.

For the interlacing shown 1:1 (i.e. each second thread in one direction is metallic) a typical surface resistance of 5 Ω/sq can thus be implemented, alternatively this surface resistance can be further reduced if the interlacing is 1:2 or 1:3, i.e. if the ratio of metallic threads 12 to non-metallic (non-conducting) fibres 10 is matched correspondingly.

In technical process terms, it is envisaged that the coating (that is to say, e.g. acrylic resin) is introduced into the fabric in a fluid state, so that, for example, the impregnation or partial penetration occurs in accordance with FIG. 1. This can, for example, happen in that the fabric is applied onto a thin layer of fluid resin and then a cross-linking of the resin subsequently takes place. Alternatively possible, and also encompassed by the invention, would be a procedure in which the coating is present in the form of a film or similar solid-state and then by a process involving, printing, temperature, or pressure (e.g., by means of lamination) is brought into contact with the fabric such that the arrangement shown in FIG. 1 results.

On an arrangement of this kind an optoelectronic device can be applied, such as is shown for example in connection with FIG. 3 (here the substrate of FIG. 1 is on top, while in a reversal of the representation of FIG. 1, the closed outer surface provided with the coating 10, faces upwards). Arrows 16 illustrate the incidence of the light onto the transparent layer 14; through the polymer material of which, and also through the transparent fibres 10 (or intermediate meshes) the light penetrates into an underlying active layer 18 that is brought into contact with the conducting fibres 12. This active layer is for example implemented in terms of PEDOT+P3HT:PCBM/C60 (for organic solar cells) or by means of TiO2/dye/electrolyte (for DSCs) and is closed off on the opposite side by a counter electrode 20. In principle, this counter electrode can also be implemented by means of the substrate in accordance with the invention.

With an open surface of approx. 80%, for example, established by a suitable choice of the mesh width, and a transmissivity for the light 16 of approx. 90% that is thereby achievable, it is possible to implement an organic or DSC solar cell that not only has favourable electrical properties, but also enables, with minimised material costs and greatly simplified processes, large cost savings compared with solar cells of known art, and radical efficiency potentials.

FIG. 2 illustrates a form of embodiment of the substrate that is a variant of that in FIG. 1, in accordance with a second example of embodiment of the present invention: here a fabric implemented from monofilaments (PA, fibre thickness 30 μm to 35 μm) is first manufactured as a fabric and after the weaving process is metallically coated, e.g. by plasma sputtering of Ag onto the fabric. Correspondingly the sectioned view of FIG. 2 shows a fabric-fibre arrangement 30, which carries a thin Ag layer (0.5 μm), if necessary additionally stabilised by means of a thin Ti coating.

This arrangement is then, in an analogous manner to the procedure in the example of embodiment of FIG. 1, provided with a non-conducting transparent polymer, so that one side (in the figure the lower side) is again completely closed and thus non-conducting, while by a suitable choice of coating thickness, an upper region protrudes of fibres that are conducting as a result of coating. Here too the surface resistance to be implemented at a value of<10 Ω/sq can be customised by other embodiments of the coating or similar, and offers the possibility, in an analogous manner to the further approach as per FIG. 3, of constructing a solar cell, an organic LED, or similar optoelectronic device thereupon.

The present invention is not limited to the examples of embodiment shown. or the above-described formulations or material groups from which selection can be made, rather, it lies within the framework of suitable dimensioning, dependent on a required application objective, to combine a suitable material strength, flexibility and load capacity of the substrate material with the desired electrical conductivity properties, wherein in the above-described manner and within the framework of the invention the materials, thicknesses, mesh widths of the fibres used can be appropriately selected or varied, along with the possibility, for purposes of implementing the electrode action, of either weaving in conducting (metallic or metallised) fibres in a suitable ratio and/or suitably metallising a fabric in the prescribed manner.

In principle it is also possible and envisaged within the framework of the invention to provide the transparent and electrically non-conducting coating in accordance with the invention such that this does not embody an electrically non-conducting surface on one side, but rather is provided in the substrate in its core region such that fibres or fibre sections protrude from the polymer on both sides of the core and so can form a conducting layer on both sides of the substrate, see for example the representation in FIG. 4. A configuration of this kind thus offers, for example, the possibility of constructing dual solar cells (tandem cells) on both sides of the substrate.

In consequence, the substrate provided by the present invention offers the possibility of radical increases in efficiency in material use and manufacture, so that one can anticipate that the photovoltaic or OLED technology (and also other optoelectronic applications) can open up many new application fields.

1-18. (canceled)

19. A substrate for an optoelectronic device, with a fabric of monofilaments and/or fibres of a polymer, which is designed for purposes of implementing and/or supporting an electrode layer, wherein the fibres have a fibre diameter of between 20 μm and 100 μm, in particular of between 30 μm and 80 μm, the fabric has mesh openings that implement an open surface area of 70 to 85%, and the fabric is provided with a coating of a transparent, electrically non-conducting polymer material, such that the fibres are at least partly surrounded by the polymer material, the coating is applied such that the substrate on a first uncoated side of the surface is electrically conducting, and on a second, coated side of the surface is electrically non-conducting.

20. The substrate in accordance with claim 19, wherein the coating is designed such that fibres or fibre sections protrude out of the coating on one or both sides of the substrate.

21. The substrate in accordance with claim 19, wherein the polymer material is designed and/or selected such that the coating is UV-resistant and/or promotes a UV-resistance of the substrate.

22. The substrate in accordance with claim 19, wherein the polymer material is designed to be radiation-cured, in particular can be UV-cross-linked, or thermally-cured.

23. The substrate in accordance with claim 19, wherein the polymer material is selected and/or applied such that the coating acts as a moisture and/or oxidation barrier for at least one side of the substrate.

24. The substrate in accordance with claim 19, wherein the polymer material is selected from the group consisting of an acrylic resin, silicon, a fluoropolymer, PU, PEN, PI, PET, PA, EVA, and mixtures thereof.

25. The substrate in accordance with claim 24, wherein the polymer material is SiOx or ORMOCER.

26. The substrate in accordance with claim 19, wherein the coating has a coating thickness that is smaller than a fabric thickness of the fabric and lies in a range between 70% and 85% of the fabric thickness.

27. The substrate in accordance with claim 19, wherein the fibres are implemented from a material that is selected from the group consisting of PA, PP, PET, PEEK, PI, PPS, PBT, PEN, and are one of semi-transparent and transparent monofilaments.

28. The substrate in accordance with claim 19, wherein a mesh width of the mesh openings lies in the range between 200 μm and 300 μm, and a surface area of a mesh opening lies in the range between 80,000 μm² and 800,000 μm².

29. The substrate in accordance with claim 19, wherein the fibres have a proportion of metallised fibres and metal fibres in the fabric at regular spacings.

30. The substrate in accordance with claim 29, wherein the metal fibres are selected from the group consisting of Ti, Mo, W, Cr, Cu, Ag, Al, Au and mixtures thereof.

31. The substrate in accordance with claim 29, wherein the metal fibres are woven into the fabric having electrically non-conducting fibres in one of a warp direction and a fill direction, wherein the fabric has no additional form of metallisation.

32. The substrate in accordance with claim 19, wherein the fabric has a form of metallisation that is applied as a coating onto the fabric.

33. The substrate in accordance with claim 29, wherein fibres that are metal and metallised, are provided in the fabric such that the fabric has a surface resistance<50 Ω/sq.

34. The substrate in accordance with claim 29, wherein fibres that are metal and metallised, are provided in the fabric such that the fabric has a surface resistance<20 Ω/sq.

35. The substrate in accordance with claim 29, wherein fibres that are metal and metallised, are provided in the fabric such that the fabric has a surface resistance<10 Ω/sq.

36. The substrate in accordance with claim 19, wherein the substrate is in combination with an optoelectronic device designed as a solar cell.

37. The substrate in accordance with claim 36, wherein the optoelectronic device is implemented as one of an OLED, display element, architectural surface element, and electronic passive component.
